(19) United States
(12) Patent Application Publication
(10) Pub. No.: US 2025/0105032 A1
(43) Pub. Date: Mar. 27, 2025

(54) CHEMICAL LIQUID SUPPLY APPARATUS, AND SUBSTRATE TREATING APPARATUS HAVING THE SAME

(71) Applicant: SAMSUNG ELECTRONICS CO., LTD., Suwon-si (KR)

(72) Inventors: Sung Hyun PARK, Suwon-si (KR); Min Suk KANG, Suwon-si (KR); Young-Hoo KIM, Suwon-si (KR); Jin Seon YOU, Suwon-si (KR); Tae-Hong KIM, Suwon-si (KR); Woo Gwan SHIM, Suwon-si (KR)

(73) Assignee: SAMSUNG ELECTRONICS CO., LTD., Suwon-si (KR)

(21) Appl. No.: 18/442,548

(22) Filed: Feb. 15, 2024

(30) Foreign Application Priority Data
Sep. 26, 2023 (KR) 10-2023-0129383

(51) Int. Cl. H01L 21/67

(52) U.S. Cl. CPC H01L 21/67075

(57) ABSTRACT

A chemical liquid supply apparatus is provided and includes an additive supply, a chemical liquid supply, and a controller that controls the additive supply and the chemical liquid supply. The additive supply includes a first tank that receives an additive from an additive container, and a first circulating pipe connected to the first tank. The chemical liquid supply includes an auxiliary tank that receives an etching liquid from another container and receives the additive, and a second circulating pipe connected to the auxiliary tank. The controller provides control so as to: circulate the additive in the first tank; heat the etching liquid in the auxiliary tank using a heater such that a temperature of the etching liquid is increased to a first temperature; supply the additive to the auxiliary tank; and produce a chemical liquid by circulating the etching liquid and the additive at the first temperature.

### CROSS-REFERENCE TO RELATED APPLICATION

This application claims priority from Korean Patent Application No. 10-2023-0129383, filed on Sep. 26, 2023, in the Korean Intellectual Property Office, and all the benefits accruing therefrom under 35 U.S.C. 119, the entire contents of which are herein incorporated by reference.

### BACKGROUND

### 1. Technical Field

Embodiments of the present disclosure relate to a chemical liquid supply apparatus and a substrate treating apparatus equipped with the same.

### 2. Description of Related Art

While semiconductor generation is changing, an etching facility is also changing from a batch type silicon nitride (SiN) etching facility to a single type silicon nitride (SiN) etching facility. The batch type silicon nitride (SiN) etching facility has disadvantages of poor dispersion, flow-related defect issues, and difficulty in selectivity control. Therefore, there is a recent trend in which the single type silicon nitride (SiN) etching facility is being developed.

The single type silicon nitride (SiN) etching facility requires development of a chemical liquid recycling system to supply high-temperature phosphoric acid chemical liquid to each of chambers and collect and recycle the used chemical liquid therefrom.

As a temperature of the phosphoric acid chemical liquid in the single type silicon nitride (SiN) etching facility increases, an etching rate may increase. In other words, as the temperature of the phosphoric acid chemical liquid increases, the etch rate on silicon nitride (SiN) may increase. However, the etch rate on not only silicon nitride (SiN) but also silica (SiO₂) may be increased. Therefore, a high etch ratio on silicon nitride (SiN) cannot be obtained. Recently, in order to satisfy both a high etch rate and a high etch ratio on silicon nitride (SiN), liquid silica is mixed with the high temperature phosphoric acid chemical liquid. However, when the temperature of the phosphoric acid chemical liquid is lowered or the phosphoric acid chemical liquid does not circulate, liquid silica may precipitate into solid silica and become a particle source, thus causing pipe clogging and sensing failure.

### SUMMARY

According to embodiments of the present disclosure, a chemical liquid supply apparatus that may maintain process consistency is provided.

According to embodiments of the present disclosure, a substrate treating apparatus that may maintain process consistency is provided.

According to embodiments of the present disclosure, a chemical liquid supply apparatus is provided and includes an additive supply, a chemical liquid supply, and a controller configured to control the additive supply and the chemical liquid supply. The additive supply includes: a first tank configured to receive an additive from an additive container; and a first circulating pipe connected to the first tank. The chemical liquid supply includes: an auxiliary tank configured to receive a raw etching liquid from a raw etching liquid container and receive the additive from the additive supply; and a second circulating pipe connected to the auxiliary tank. The controller is configured to control the additive supply and the chemical liquid supply so as to: circulate the additive in the first tank for a first time using the first circulating pipe; heat the raw etching liquid in the auxiliary tank using a heater such that a temperature of the raw etching liquid is increased from room temperature to a first temperature; based on the temperature of the raw etching liquid reaching the first temperature, supply the additive to the auxiliary tank; and produce a chemical liquid by circulating the raw etching liquid and the additive at the first temperature for a second time using the second circulating pipe.

According to embodiments of the present disclosure, a substrate treating apparatus is provided and includes: an additive supply; a chemical liquid supply; a processing unit; and a controller configured to control the additive supply and the chemical liquid supply. The additive supply includes: a first tank configured to receive an additive from an additive container; and a first circulating pipe connected to the first tank. The chemical liquid supply includes: an auxiliary tank for receiving a raw etching liquid from a raw etching liquid container and receiving the additive from the additive supply; a second circulating pipe connected to the auxiliary tank; and a main tank configured to receive and store a chemical liquid from the auxiliary tank. The processing unit includes including a process chamber, a substrate, and a substrate support, the processing unit configured to receive the chemical liquid from the chemical liquid supply. The controller is configured to control the additive supply and the chemical liquid supply so as to: circulate the additive in the first tank for a first time using the first circulating pipe; heat the raw etching liquid in the auxiliary tank using a heating device such that a temperature of the raw etching liquid is increased from room temperature to a first temperature; based on the raw etching liquid reaching the first temperature, supply the additive to the auxiliary tank; produce the chemical liquid by circulating the raw etching liquid and the additive at the first temperature for a second time using the second circulating pipe; and supply the chemical liquid to the processing unit.

According to embodiments of the present disclosure, a chemical liquid supply apparatus is provided and includes: an additive container containing an additive; a first tank configured to receive the additive from the additive container and store the additive; a first circulating pipe connected to the first tank and configured to circulate the additive in the first tank; a first supply pipe connected to the first circulating pipe and configured to supply the additive, wherein the first supply pipe includes a filter; an auxiliary tank configured to receive a raw etching liquid from a raw etching liquid container and receive the additive from the first supply pipe; a second circulating pipe connected to the auxiliary tank and configured to circulate a chemical liquid in the auxiliary tank, wherein the chemical liquid includes the raw etching liquid and the additive added to the raw etching liquid; a heater connected to the second circulating pipe and configured to heat the chemical liquid; a main tank configured to receive the chemical liquid from the auxiliary tank and store the chemical liquid; a processing unit including a process chamber, a substrate, and a substrate support, the processing unit configured to receive the chemical liquid from the main tank; and a controller configured to perform control so as to: circulate the additive in the first tank for a first time using the first circulating pipe; heat the raw etching liquid in the auxiliary tank using an additional heater such that a temperature of the raw etching liquid is increased from room temperature to a first temperature; based on the temperature of the raw etching liquid reaching the first temperature, supply the additive to the auxiliary tank; produce the chemical liquid by circulating the raw etching liquid and the additive at the first temperature for a second time using the second circulating pipe; and supply the chemical liquid to the main tank.

Aspects of embodiments of the present disclosure are not limited to the above-mentioned aspects. Other aspects and advantages according to embodiments of the present disclosure that are not mentioned may be understood based on following descriptions, including descriptions of non-limiting example embodiments of the present disclosure. Further, it will be easily understood that purposes and advantages of embodiments of the present disclosure may be realized using means described in the claims or combinations thereof.

### BRIEF DESCRIPTION OF DRAWINGS

The above and other aspects and features of embodiments of the present disclosure will become more apparent by describing in detail non-limiting example embodiments of the present disclosure with reference to the attached drawings, in which:

FIG. 1 is a schematic diagram for illustrating a chemical liquid supply apparatus and a substrate treating apparatus equipped with the same according to some embodiments of the present disclosure.

FIG. 2 is a diagram for illustrating the auxiliary tank and the second circulating pipe in FIG. 1

FIG. 3 is a schematic diagram for illustrating a substrate treating apparatus according to some embodiments of the present disclosure.

FIG. 4 is a graph for illustrating an effect of the chemical liquid supply apparatus according to some embodiments of the present disclosure.

FIG. 5 is a graph for illustrating an effect of the chemical liquid supply apparatus according to some embodiments of the present disclosure.

FIG. 6 is a graph for illustrating an effect of the chemical liquid supply apparatus according to some embodiments of the present disclosure.

FIG. 7 is a graph for illustrating an effect of the chemical liquid supply apparatus according to some embodiments of the present disclosure.

FIG. 8 is a diagram for illustrating a chemical liquid circulating time in the chemical liquid supply.

FIG. 9 is a graph for illustrating an effect of the chemical liquid supply apparatus according to some embodiments of the present disclosure.

FIG. 10 is a graph for illustrating an effect of the chemical liquid supply apparatus according to some embodiments of the present disclosure.

FIG. 11 is a diagram for illustrating a chemical liquid supply method according to some embodiments of the present disclosure.

FIG. 12 is a diagram for illustrating a substrate treatment method according to some embodiments of the present disclosure.

### DETAILED DESCRIPTION

Although the terms “first,” “second,” etc. may be used herein to describe various elements or components, these elements or components should not be limited by these terms. These terms are used to distinguish one element or component from another element or component. Thus, a first element or component discussed below could be termed a second element or component without departing from the teachings of the present disclosure.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

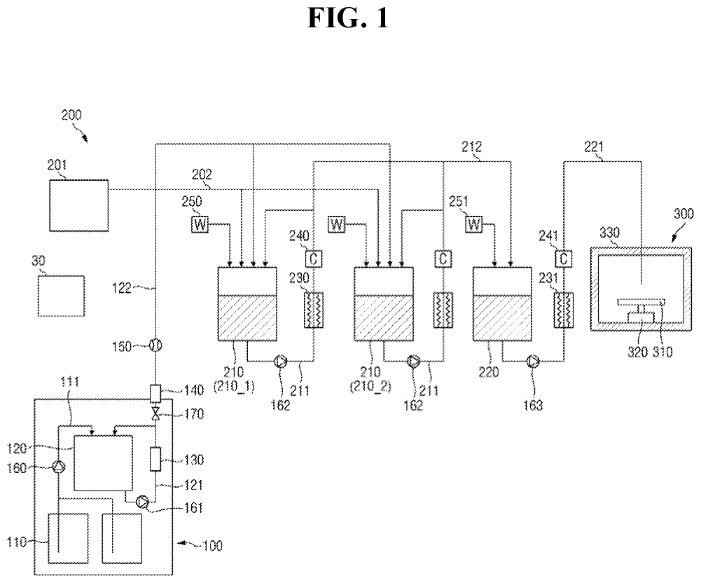

FIG. 1 is a schematic diagram for illustrating a chemical liquid supply apparatus and a substrate treating apparatus equipped with the same according to some embodiments of the present disclosure.

Referring to FIG. 1, the chemical liquid treating apparatus may include an additive supply 100, a chemical liquid supply 200, and a controller 30. The substrate treating apparatus may include the chemical liquid treating apparatus and may further include a processing unit 300.

The additive supply 100 may include an additive container 110, a first pipe 111, a pump 160, a first tank 120, a first circulating pipe 121, a liquid particle counter (LPC) 130, a first supply pipe 122, a filter 140, and a valve 170.

The additive container 110 may contain therein an additive. The additive may be a silicon compound. In some embodiments, the additive may be a mixture of water (H₂O) and silica (SiO₂). When the additive is mixed with phosphoric acid, an etching rate of silicon nitride (SiN) may be increased.

The first pipe 111 may be connected to the additive container 110. The first pipe 111 may be inserted into the additive container 110. The first pipe 111 may include a pump 160. The first pipe 111 may supply the additive from the additive container 110 via the pump 160. The first pipe 111 may be connected to the first tank 120. The first pipe 111 may supply the additive in the additive container 110 to the first tank 120.

The first tank 120 may receive the additive from the additive container 110 via the first pipe. The first tank 120 may store the supplied additive therein. The first tank 120 may have a larger volume than a volume of the additive container 110. In some embodiments, the volume of the first tank 120 may be 70 L. However, embodiments of the present disclosure are not limited thereto.

The first circulating pipe 121 may be connected to the first tank 120. The first circulating pipe 121 may be connected to a top and a bottom of the first tank 120. The first circulating pipe 121 may include a pump 161. The first circulating pipe 121 may circulate the additive within the first tank 120 for a first time. The first time may be a time duration elapsed until a concentration of the silica in the additive becomes constant. The additive may be a mixture of water and silica. In this regard, when the additive is supplied directly from the additive container 110, the concentration of the silica in the additive may vary depending on a vertical level in the additive container 110. However, when the additive has been circulated within the first tank 120 through the first circulating pipe 121 for the first time, the silica concentration may be maintained constant therein.

The liquid particle counter 130 may be connected to the first circulating pipe 121. The liquid particle counter 130 may measure a concentration of fine particles in liquid flowing through the first circulating pipe 121. The liquid particle counter 130 may detect light scattered from the fine particles in the liquid, and may measure a size of the particles, and analyze the particle distribution based on the detected light. For example, the liquid particle counter 130 connected to the first circulating pipe 121 may measure the size and the concentration of particles contained in the additive. Specifically, the particle size and the concentration of the silica contained in the additive may be measured using the liquid particle counter 130.

The first supply pipe 122 may be connected to the first circulating pipe 121. The first supply pipe 122 may supply the additive to an outside. For example, the first supply pipe 122 may supply the additive to the chemical liquid supply 200. The first supply pipe 122 may supply the additive to an auxiliary tank 210, which will be described later.

The first supply pipe 122 may be connected to the valve 170. Whether or not the additive is fed to the chemical liquid supply 200 may be determined depending on whether the valve 170 is opened or closed.

The first supply pipe 122 may include the filter 140. The filter 140 may be formed in a cylindrical shape. However, embodiments of the present disclosure are not limited thereto. The filter 140 may have a porous form. For example, the filter 140 may include a plurality of holes. In some embodiments, a pore size of the filter 140 may be 10 μm. However, embodiments of the present disclosure are not limited thereto. Large-sized silica particles larger than the pore size may be captured by the filter 140.

The first supply pipe 122 may include a flow meter 150. The flow meter 150 may measure a flow rate of the additive being supplied to the chemical liquid supply 200. Based on the flow rate of the additive measured by the flow meter 150, the flow rate of the additive may be adjusted. In some embodiments, the flow meter 150 may be a flow meter for a chemical (e.g., for a slurry). Since the additive may contain the silica particles, additive supply accuracy may be improved when using the flow meter for the slurry.

The chemical liquid supply 200 may include at least one auxiliary tank 210, at least one second circulating pipe 211, at least one heating device 230 (e.g., heater), at least one concentration meter 240, at least one water container 250, a main tank 220, and a second supply pipe 221,

The at least one auxiliary tank 210 may include a first auxiliary tank 210_1 and a second auxiliary tank 210_2. The at least one auxiliary tank 210 may be connected to the additive supply 100 via the first supply pipe 122. The at least one auxiliary tank 210 may receive the additive from the additive supply 100 via the first supply pipe 122. Each of the at least one auxiliary tank 210 may be connected to a raw etching liquid container 201 via a second pipe 202. Each of the at least one auxiliary tank 210 may receive a raw etching liquid from the raw etching liquid container 201 via the second pipe 202. In this regard, the raw etching liquid may be an aqueous phosphoric acid solution (H₃O₄P). Each of the at least one auxiliary tank 210 may be connected to a same or different one among the at least one water container 250. The at least one auxiliary tank 210 may receive water from the at least one water container 250. In this regard, the water may be de-ionized water (DIW).

The at least one auxiliary tank 210 may contain chemical liquid. The chemical liquid may be a mixture of the raw etching liquid and the additive. In some embodiments, the chemical liquid may be a mixture of the aqueous phosphoric acid solution and the silica compound as the additive.

A respective second circulating pipe 211 may be connected to each of the at least one auxiliary tank 210. Each second circulating pipe 211 may include a pump 162. Each second circulating pipe 211 may circulate the raw etching liquid supplied to the auxiliary tank 210 connected to the second circulating pipe 211. The second circulating pipe 211 may circulate the chemical liquid as the mixture of the additive and the raw etching liquid for a second time. The second time may be a time duration for which the additive has been dissolved in the raw etching liquid.

A respective heating device 230 may be connected to each second circulating pipe 211. The heating device 230 may heat the raw etching liquid or the chemical liquid stored in the second circulating pipe 211 to a first temperature. The first temperature may be in a range of 160° C. to 170° C. The first temperature may be a temperature for increasing the solubility at which the additive is dissolved in the raw etching liquid. According to embodiments of the present disclosure, the controller 30 may control each heating device 230 to heat the raw etching liquid or the chemical liquid stored in the at least one second circulating pipe 211 to the first temperature. According to embodiments of the present disclosure, at least one sensor may be provided in or near the at least one second circulating pipe 211 or the at least one heating device 230, and the controller 30 may control the at least one heating device 230 to heat the raw etching liquid or the chemical liquid stored in the at least one second circulating pipe 211 to the first temperature based on a temperature(s) sensed by the at least one sensor.

In some embodiments, the chemical liquid supply apparatus may include a chemical liquid supply sequence. First, the raw etching liquid is provided from the raw etching liquid container 201 to the at least one auxiliary tank 210. Then, the raw etching liquid is heated from room temperature to the first temperature using the at least one heating device 230. When the temperature of the raw etching liquid has reached the first temperature, the additive is supplied from the additive supply 100 to the at least one auxiliary tank 210. After supplying the additive to the at least one auxiliary tank 210, the chemical liquid (raw etching liquid+additive) has been circulated for the second time at the first temperature using the at least one second circulating pipe 211. After being subjected to the above steps, the chemical liquid is supplied to the main tank 220. According to embodiments of the present disclosure, the controller 30 may control the chemical liquid supply apparatus to perform the chemical liquid supply sequence. For example, the controller 30 may control valves (e.g., the valve 170, and other valves that may be connected to the raw etching liquid container 201 and/or the at least one water container 250), pumps (e.g., the pump 160, the pump 161, the pump 162, and other pumps that may be connected to the raw etching liquid container 201 and/or the at least one water container 250), and heaters (e.g., the at least one heating device 230) to cause the chemical liquid supply sequence to be performed, and the control may be based on receiving temperature values from the at least one sensor and/or concentration values from the at one concentration meter 240 and/or the liquid particle counter 130.

When the solubility of the additive is lowered due to the low temperature of the raw etching liquid, the silica may precipitate, causing a problem that may clog a pipe. When the temperature of the raw etching liquid is increased from room temperature to the first temperature and then the raw etching liquid is mixed with the additive, the solubility of the additive in the raw etching liquid may be increased. Therefore, according to embodiments of the present disclosure, the pipe clogging occurring when the silica is precipitated in the circulating pipe may be reduced.

Additionally, when the chemical liquid containing the raw etching liquid and the additive does not circulate, the silica may precipitate to clog the pipe and an etch selectivity may change during the etching process. According to embodiments of the present disclosure, when the chemical liquid has been circulated at the first temperature for the second time such that the additive is sufficiently dissolved in the raw etching liquid, the pipe clogging may be reduced, and a constant etch selectivity may be obtained during the etching process.

A respective concentration meter 240 may be connected to each of the at least one second circulating pipe 211. The concentration meter 240 may measure the silica concentration in the chemical liquid. When the concentration measured by the concentration meter 240 is outside a set concentration, the water may be provided from the water container 250 to the chemical liquid to adjust the silica concentration.

The main tank 220 may be connected to each of the at least one auxiliary tank 210 via a third pipe 212. The main tank 220 may receive the chemical liquid from the auxiliary tank 210 and store therein the chemical liquid. According to embodiments of the present disclosure, the main tank 220 may be connected to a water container 251.

The second supply pipe 221 may be connected to the main tank 220. The second supply pipe 221 may provide the chemical liquid from the main tank 220 to the processing unit 300. According to embodiments of the present disclosure, the second supply pipe 221 may be connected to a pump 163, a heating device 231, and a concentration meter 241. The function of the water container 251, the pump 163, the heating device 231, and the concentration meter 241 may be the same or similar to the function of the water container 250, the pump 162, and the heating device 230, and the concentration meter 240.

The controller 30 may control the additive supply 100 and the chemical liquid supply 200. In some embodiments, the controller 30 may control the additive supply process of the additive supply 100 and the chemical liquid supply process of the chemical liquid supply 200. Specifically, the controller 30 may be configured to circulate the additive in the first tank 120 for the first time using the first circulating pipe 121, and heat the raw etching liquid in the auxiliary tank 210 such that the temperature thereof is increased from the room temperature to the first temperature. Further, when the temperature of the raw etching liquid has reached the first temperature, the controller 30 may be configured to supply the additive to the auxiliary tank 210, and circulate the raw etching liquid and the additive for the second time using the second circulating pipe 211 at the first temperature to produce the chemical liquid. Additionally, the controller 30 may be configured to supply the chemical liquid from the at least one auxiliary tank 210 to the main tank 220, and then to the processing unit 300. According to embodiments of the present disclosure, the controller 30 may control the additive supply process and the chemical liquid supply process by controlling valves (e.g., the valve 170 and other valves that may be connected to the raw etching liquid container 201, the at least one water container 250, and/or the water container 251), pumps (e.g., the pump 160, the pump 161, the pump 162, a pump 163, and other pumps that may be connected to the raw etching liquid container 201, the at least one water container 250, and/or the water container 250), and heaters (e.g., the at least one heating device 230 and/or the heating device 231) to cause the chemical liquid supply sequence to be performed, and the control may be based on receiving temperature values from the at least one sensor and/or concentration values from the at one concentration meter 240, the concentration meter 241, and/or the liquid particle counter 130.

The processing unit 300 may include a substrate 310, a substrate support 320, and a process chamber 330.

The substrate 310 may be seated on the substrate support 320. The substrate support 320 may support the substrate 310 thereon and may rotate the substrate 310 during a process. The process chamber 330 may be connected to the second supply pipe 221. The process chamber 330 may receive the chemical liquid from the second supply pipe 221. Within the process chamber 330, a wet etching process may be performed on the substrates using the supplied chemical liquid.

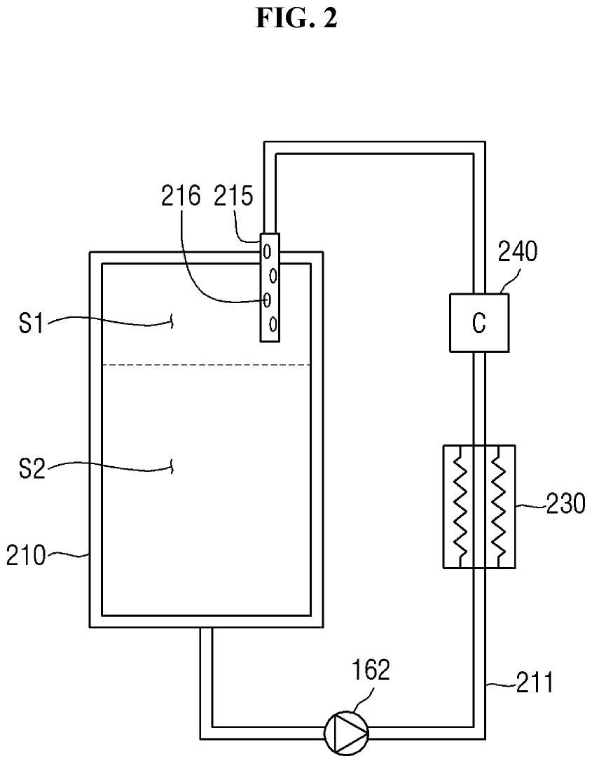

FIG. 2 is a diagram for illustrating the auxiliary tank and the second circulating pipe in FIG. 1. For convenience of description, contents duplicate with what has been described above with reference to FIG. 1 may be briefly described or omitted.

Referring to FIG. 2, each of the at least one auxiliary tank 210 may be connected to the second circulating pipe 211. The auxiliary tank 210 may include a first area S1 and a second area S2. The first area S1 may be located above the second area S2. The first area S1 may be an upper area of the auxiliary tank 210. Specifically, the first area S1 may be an area corresponding to ⅓ of the volume of the auxiliary tank 210. The second area S2 may be a lower area of the auxiliary tank 210. Specifically, the second area S2 may be an area corresponding to ⅔ of the volume of the auxiliary tank 210.

A discharge pipe 215 may be connected to the second circulating pipe 211. The discharge pipe 215 may be located in the first area S1 of the auxiliary tank 210. The discharge pipe 215 may include a plurality of holes 216. The discharge pipe 215 may discharge the circulated raw etching liquid or the chemical liquid to the auxiliary tank 210. For example, the plurality of holes 216 of the discharge pipe 215 may discharge the circulated raw etching liquid or the chemical liquid to the first area S1 of the auxiliary tank 210.

When the raw etching liquid or the chemical liquid is discharged in one direction, a dissolution rate of the additive in the raw etching liquid may decrease. When the discharge pipe is located in the first area S1 and includes the plurality of holes 216, the raw etching liquid or the chemical liquid may be discharged in multiple directions rather than in one direction, so that the dissolution rate of the additive in the raw etching liquid may be accelerated.

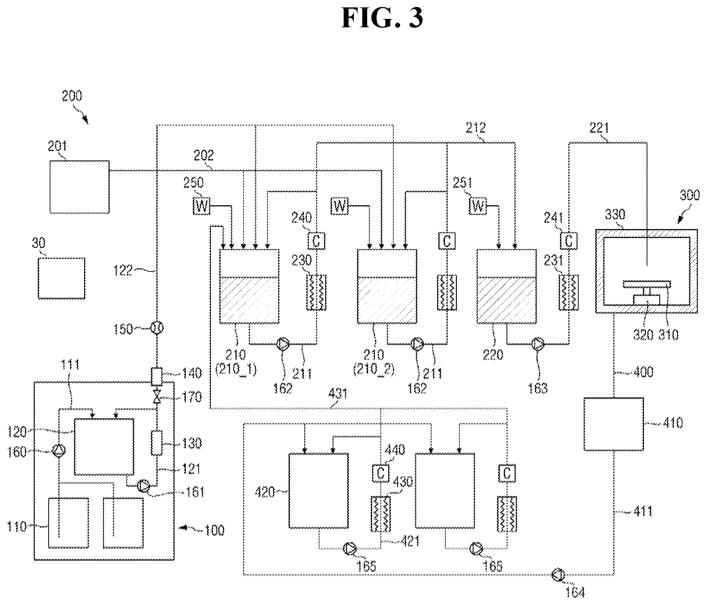

FIG. 3 is a schematic diagram for illustrating a substrate treating apparatus according to some embodiments of the present disclosure. For convenience of description, contents duplicate with what has been described above with reference to FIG. 1 may be briefly described or omitted.

Referring to FIG. 3, the substrate treating apparatus may include the additive supply 100, the chemical liquid supply 200, the processing unit 300, and the controller 30.

The description of each of the additive supply 100 and the processing unit 300 may be substantially the same as the description provided above with reference to FIG. 1, and thus is not repeated.

The chemical liquid supply 200 may include the at least one auxiliary tank 210, the at least one second circulating pipe 211, the main tank 220, a collection tank 410, at least one recycling tank 420, and at least one third circulating pipe 421.

The description of each of the at least one auxiliary tank 210, the at least one second circulating pipe 211, and the main tank 220 may be substantially the same as the description provided above with reference to FIG. 1, and thus is not repeated.

The collection tank 410 may be connected to the processing unit 300 via a collection pipe 400. The collection tank 410 may collect the chemical liquid remaining after use in the process chamber 330. For example, after performing the wet etching process on the substrate in the process chamber 330, the remaining chemical liquid may be collected into the collection tank 410 via the collection pipe 400.

The at least one recycling tank 420 may receive the chemical liquid from the collection tank 410. The at least one recycling tank 420 may store therein the chemical liquid. The at least one recycling tank 420 and the collection tank 410 may be connected to each other via a fourth pipe 411. As shown in FIG. 3, the at least one recycling tank 420 is provided as two recycling tanks 420. However, embodiments of the present disclosure are not limited thereto. For example, there may be one or three or more of the recycling tank 520.

A respective third circulating pipe 421 may be connected to each of the at least one recycling tank 420. Each third circulating pipe 421 may include a heating device 430 and a concentration meter 440. The third circulating pipe 421 may circulate the chemical liquid stored in the recycling tank 420 at the first temperature for a third time. The third time may be the time when silica is dissolved in the collected chemical liquid. The temperature of the chemical liquid that has undergone the wet etching process in the process chamber 330 may be lowered. The silica may precipitate from the chemical liquid whose the temperature has been lowered. In order to reuse the collected chemical liquid, the collected chemical liquid may be circulated at the first temperature for a third time and then may be supplied, thereby preventing the silica from precipitating and thus preventing the clogging of the pipe. According to embodiments of the present disclosure, the controller 30 may control each heating device 430 to heat the chemical liquid stored in the at least one third circulating pipe 421 to the first temperature. According to embodiments of the present disclosure, at least one sensor may be provided in or near the at least one third circulating pipe 421 or the at least one heating device 430, and the controller 30 may control the at least one heating device 430 to heat the chemical liquid stored in the at least one third circulating pipe 421 to the first temperature based on a temperature(s) sensed by the at least one sensor.

The third supply pipe 431 may be connected to the at least one third circulating pipe 421. The at least one first auxiliary tank 210 may receive the collected chemical liquid via the third supply pipe 431. The first auxiliary tank 210_1 of the auxiliary tank 210 may receive the collected chemical liquid, while the second auxiliary tank 210_2 thereof may not receive the collected chemical liquid. The collected chemical liquid may be supplied from the first auxiliary tank 210_1 to the main tank 220.

The controller 30 may control a series of processes that occur between the collection tank 410, the at least one recycling tank 420, the at least one third circulating pipe 421, and the third supply pipe 431. For example, the controller 30 may be configured to supply the collected chemical liquid from the collection tank 410 to the at least one recycling tank 420, to circulate the chemical liquid in the recycling tank 420 using the at least one third circulating pipe 421, and then, supply the chemical liquid from the recycling tank 420 to the first auxiliary tank 210_1. For example, the controller 30 may control a pump 164 connected to the fourth pipe 411 and at least one pump 165 connected to the at least one third circulating pipe 421 so as to control the circulation and supply of the chemical liquid. According to embodiments of the present disclosure, the control may be based on the controller 30 receiving temperature values from the at least one sensor and/or concentration values from the at one concentration meter 440.

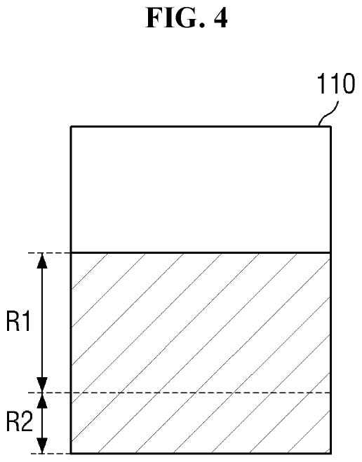

FIGS. 4 to 7 are diagrams for illustrating an effect of the chemical liquid supply apparatus according to some embodiments of the present disclosure. FIGS. 4 to 6 are graphs of results obtained when the additive from the additive container 110 is used directly without the at least one first tank 120 and the at least one first circulating pipe 121.

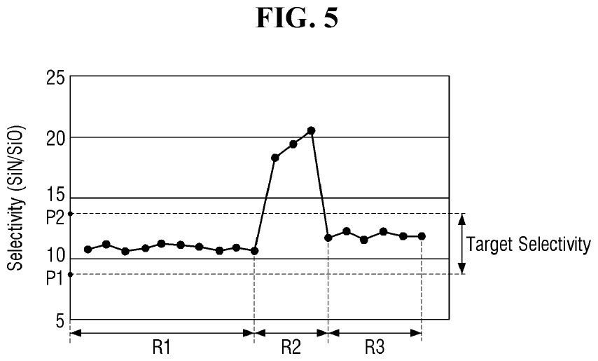

FIG. 5 is a graph showing the etch selectivity (SiN/SiO) of the silicon nitride (SiN) and the silica (SiO₂) in the wet etching process when the additive has been used in each of the areas. A first area R1 in a horizontal axis corresponds to use of the additive present in an area between a first vertical level spaced vertically by 10 cm from the bottom of the additive container 110 and a second vertical level above the first vertical level (see FIG. 4). A second area R2 in the horizontal axis corresponds to use of the additive present in an area between the bottom of the additive container 110 and the first vertical level (see FIG. 4). A third area R3 in the horizontal axis corresponds to use of the additive immediately after replacing the additive container 110. A vertical axis in FIG. 5 represents the etch selectivity (SiN/SiO) of the silicon nitride (SiN) and the silica (SiO₂) when the additive in the additive container 110 has been used.

A target selectivity range is defined between a first value P1 and a second value P2 in the vertical axis. When the additive in each of the first area R1 and the third area R3 has been used, the etch selectivity is within the target selectivity range. However, when the additive in the second area R2 has been used, the etch selectivity is outside the target selectivity range.

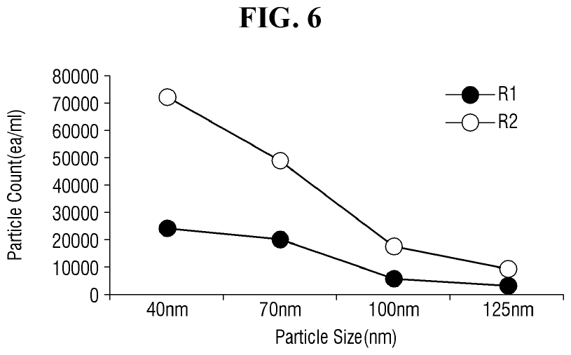

FIG. 6 is a graph of a measuring result of the additive concentration in the chemical liquid using the liquid particle counter. Specifically, the graph shows a measuring result of the additive concentration used in the first area R1 in the chemical liquid and the additive concentration used in the second area R2 in the chemical liquid. A horizontal represents the size of the particles and a vertical axis represents the number of particles. It may be identified that the number of particles in the chemical liquid in the second area R2 is greater than that in the first area R1. Thus, it may be identified that the additive concentration used in the second area R2 is higher. Additionally, it may be identified that the concentration of silica in the additive used in the second area R2 is higher than the concentration of silica in the additive used in the first area R1.

The additive may be a mixture of water and silica. When the concentration of silica in the additive increases, the etch selectivity (SiN/SiO) of the silicon nitride and the silica may increase. Referring to the graphs in FIG. 5 and FIG. 6, the silica concentration of the additive in the second area R2 is greater than the silica concentration of the additive in each of the first area R1 and the third area R3. In conclusion, the concentration of the additive may vary depending on a vertical level of the additive container.

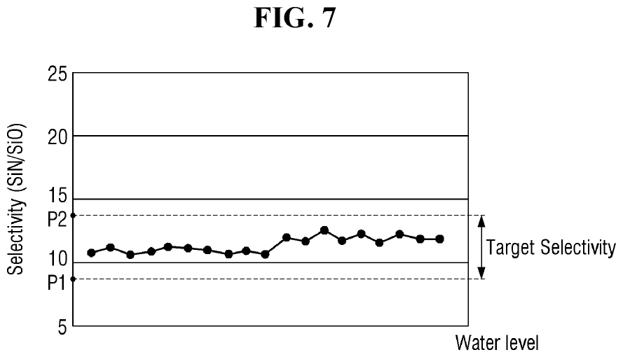

FIG. 7 is a graph showing when the additive has been used using the first tank 120 and the first circulating pipe 121 in the additive supply 100. A horizontal axis represents a water level of the additive in the first tank 120. A vertical axis represents the etch selectivity of each of silicon nitride (SiON) and silica (SiO₂) when the additive in the first tank 120 has been used.

In FIG. 7, when the additive in the first tank 120 has been used, the etch selectivity is consistently within the target selectivity range. When the additive has been circulated for the first time using the first circulating pipe 121 after supplying the additive from the additive container 110 to the first tank 120, a variation in an additive concentration in the chemical liquid based on a vertical level of the additive container 110 may be prevented.

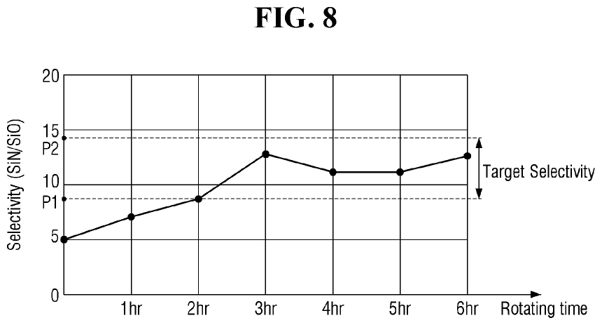

FIG. 8 is a diagram for illustrating a chemical liquid circulating time in the chemical liquid supply. FIG. 8 shows data on the etch selectivity of each of silicon nitride and silica based on the chemical liquid circulating time in the auxiliary tank 210 of a volume of 70 L while the temperature of the chemical liquid is set to the first temperature. A horizontal axis represents a time for which the chemical liquid has been circulated using the second circulating pipe 211, and a vertical axis represent the etch selectivity (SiN/SiO) of silicon nitride and silica. The target selectivity range is defined between the first value P1 and the second value P2. It may be identified that under the above condition, when the circulating time is 1 hour or 2 hours, the etch selectivity (SiN/SiO) is outside the target selectivity range. It may be identified that when the circulating time is larger than or equal to 3 hours, the etch selectivity is within the target selectivity range. Thus, it may be identified that a sufficient chemical liquid circulating time may be provided to obtain the target selectivity. The chemical liquid circulation time may be related to a time for which the additive has been dissolved in the chemical liquid. The additive may be dissolved in the chemical liquid to obtain a desired etch selectivity.

Therefore, the chemical liquid supply apparatus may perform a following process. After supplying the raw etching liquid to the auxiliary tank 210, the temperature is raised from the room temperature to the first temperature. Then, after supplying the additive, the chemical liquid has been circulated for the second time using the second circulating pipe 211 at the first temperature. The second time may be the time duration for which the additive has been dissolved in the raw etching liquid. Through this process, the desired etch selectivity may be obtained in the wet etching process.

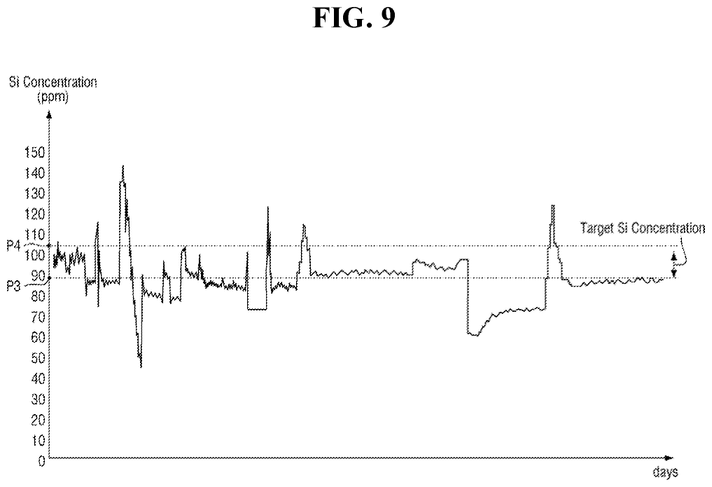

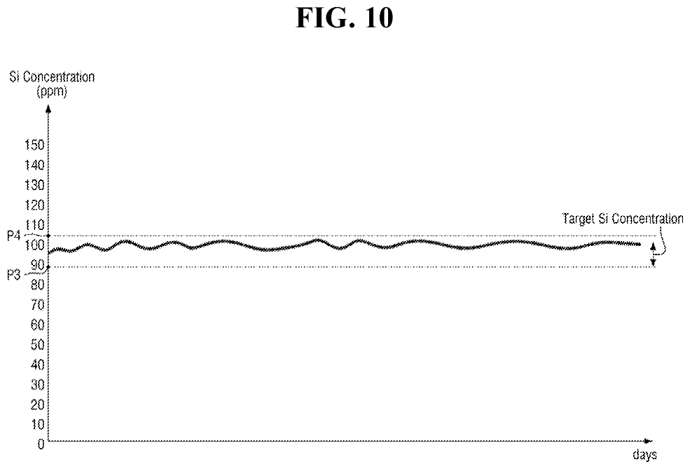

FIG. 9 and FIG. 10 are graphs for illustrating an effect of the chemical liquid supply apparatus according to some embodiments of the present disclosure. FIG. 9 and FIG. 10 are graphs showing a Si concentration in the chemical liquid over time (days).

FIG. 9 and FIG. 10 are graphs before and after applying a chemical liquid supply process using the chemical liquid supply apparatus according to the present disclosure, respectively. In FIG. 9 and FIG. 10, a horizontal axis represents a time (days). A vertical axis represents the Si concentration in the chemical liquid in the chemical liquid supply apparatus. A target Si concentration is defined between a third value P3 and a fourth value P4 along the vertical axis. It may be identified that in FIG. 9 showing the measurement result before applying the chemical liquid supply process using the chemical liquid supply apparatus according to the present disclosure, the Si concentration in the chemical liquid is not constant over time. On the contrary, it may be identified that in FIG. 10 showing the measurement result after applying the chemical liquid supply process using the chemical liquid supply apparatus according to the present disclosure, the Si concentration in the chemical liquid is within the target Si concentration range over time.

The desired etch selectivity may be obtained only when the Si concentration in the chemical liquid is within the target Si concentration range. When applying the chemical liquid supply process as described in FIG. 1, the Si concentration in the chemical liquid may be kept constant, and the target etch selectivity may be obtained during the etching process.

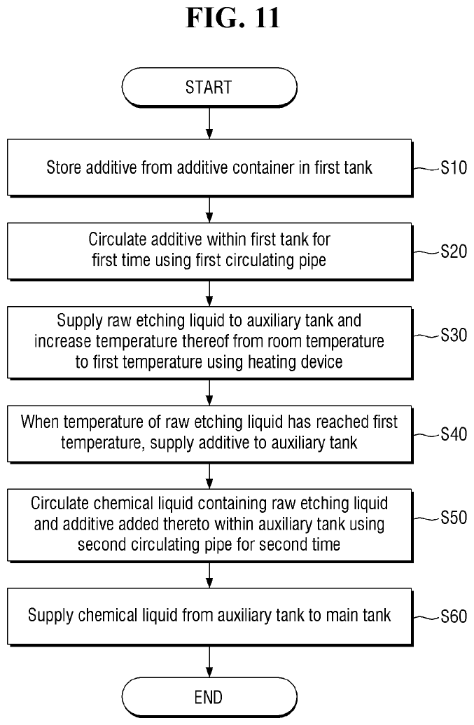

FIG. 11 is a diagram for illustrating a chemical liquid supply method according to some embodiments of the present disclosure.

As shown in FIG. 1, the chemical liquid supply apparatus including the additive supply 100 and the chemical liquid supply 200 may be provided.

Referring to FIG. 11, first, the additive from the additive container 110 is stored in the first tank 120 in operation S10.

In this regard, the additive may be a mixture of water and silica. The additive is supplied through the first pipe 111 to the first tank 120 and is stored in the first tank 120.

Next, the additive is circulated within the first tank 120 for the first time using the first circulating pipe 121 in operation S20.

The first time may be the time duration elapsed until the concentration of silica in the additive becomes constant. When the additive supplied from the additive container 110 is immediately used, the concentration of silica may vary depending on a vertical level of the tank containing the additive. The varying silica concentration may adversely affect the etch selectivity. When the additive has been circulated in the first tank 120 for the first time, the concentration of silica in the additive may become constant.

Next, the raw etching liquid is supplied to the at least one auxiliary tank 210 and the temperature of the raw etching liquid is raised from room temperature to the first temperature using the heating device 230 in operation S30.

Rather than supplying the raw etching liquid and the chemical liquid to the at least one auxiliary tank 210 at the same time, the raw etching liquid is supplied first thereto and then heated. When the temperature of the raw etching liquid is raised from the room temperature to the first temperature, the solubility of the additive in the raw etching liquid may increase. In this regard, the first temperature may be the temperature for increasing a solubility of the additive in the raw etching liquid. In some embodiments, the first temperature may be in a range of 160° C. to 170° C.

Next, when the temperature of the raw etching liquid has reached the first temperature, the additive is supplied to the at least one auxiliary tank 210 in operation S40.

When the additive is supplied to the at least one auxiliary tank 210 after the temperature of the raw etching liquid has reached the first temperature, the additive may be easily dissolved in the raw etching liquid. When the raw etching liquid temperature is low, the solubility of the additive therein decreases. When the solubility of the additive decreases, the silica of the additive may precipitate to cause the pipe clogging. When the raw etching liquid has been heated to the first temperature and then the additive is added thereto, the pipe clogging due to the silica precipitation may be prevented.

Next, the chemical liquid containing the raw etching liquid and the additive added thereto is circulated within the at least one auxiliary tank 210 using the at least one second circulating pipe 211 for the second time in operation S50.

The chemical liquid has been circulated for the second time using the at least one second circulating pipe211 at the first temperature such that the additive is dissolved in the chemical liquid. The additive should be sufficiently dissolved therein to obtain the desired etch selectivity.

Next, the chemical liquid is supplied from the at least one auxiliary tank 210 to the main tank 220 in operation S60.

The chemical liquid in which the additive is sufficiently dissolved is supplied from the at least one auxiliary tank 210 to the main tank 220.

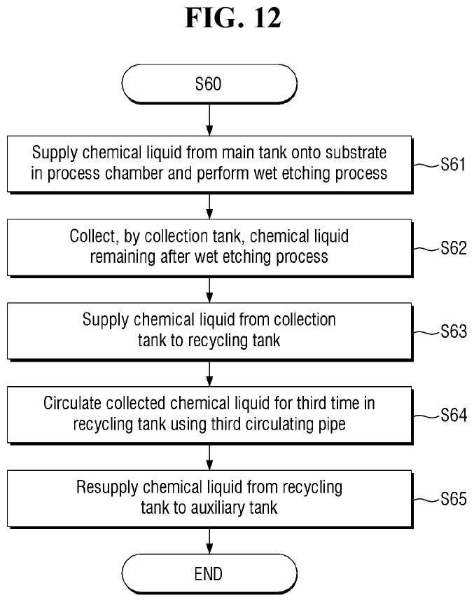

FIG. 12 is a diagram for illustrating a substrate treatment method according to some embodiments of the present disclosure.

As shown in FIG. 3, the substrate treating apparatus, including the additive supply 100, the chemical liquid supply 200, the processing unit 300, the collection tank 410, the at least one recycling tank 420, and the at least one third circulating pipe 421 may be provided.

Referring to FIG. 12, after supplying the chemical liquid from the at least one auxiliary tank 210 to the main tank in S60 as described above in FIG. 11, the chemical liquid is supplied from the main tank 220 onto the substrate 310 in the process chamber 330 and the wet etching process is performed in operation S61.

Next, the collection tank 410 collects the chemical liquid remaining after the wet etching process in operation S62.

The collection tank 410 is connected to the process chamber 330 and may collect the chemical liquid remaining after the wet etching process.

Next, the chemical liquid is supplied from the collection tank 410 to the at least one recycling tank 420 in operation S63.

In order to reuse the chemical liquid, the fourth pipe 411 may be used to supply the chemical liquid from the collection tank 410 to the at least one recycling tank 420.

Next, the collected chemical liquid is circulated for the third time in the at least one recycling tank 420 using the at least one third circulating pipe 421 in operation S64.

As the temperature of the collected chemical liquid decreases, silica may precipitate. Therefore, when the collected chemical liquid has been circulated for the third time using the at least one third circulating pipe 421 at the first temperature, the additive may be dissolved in the chemical liquid.

In this regard, the third time may be the time for which the additive has been dissolved in the collected chemical liquid.

Next, the chemical liquid is resupplied from the at least one recycling tank 420 to the at least one auxiliary tank 210 in operation S65.

To reuse the collected chemical liquid, the chemical liquid is supplied to the at least one auxiliary tank 210. The at least one auxiliary tank 210 may include the first auxiliary tank 210_1 and the second auxiliary tank 210_2. The collected chemical liquid is supplied to the first auxiliary tank 210_1. The chemical liquid supplied to the at least one auxiliary tank 210 may be supplied to the main tank 220, and then from the main tank 220 to the process chamber 330, and then may be reused in the etching process.

According to embodiments of the present disclosure, the controller 30 may include at least one processor and memory storing computer instructions. The computer instructions may be configured to cause, when executed by the at least one processor, the controller 30 to perform its functions. For example, the computer instructions may cause the controller 30 to perform the chemical liquid supply method of FIG. 11 and/or the substrate treatment method of FIG. 12. According to embodiments of the present disclosure, the controller 30 may be configured to control the various components of the substrate treating apparatuses, including the components of the chemical liquid treating apparatuses, of embodiments of the present disclosure to perform their respective functions. According to embodiments of the present disclosure, the controller 30 may be configured to perform one or more of its functions based on receiving signals from one or more sensors of the substrate treating apparatuses. For example, the sensors may include temperature sensors, the at one concentration meter 240, the concentration meter 241, the liquid particle counter 130, etc.

Although example embodiments of the present disclosure have been described above with reference to the accompanying drawings, the present disclosure is not limited to the example embodiments and may be implemented in various different forms. Those of ordinary skill in the technical field to which the present disclosure belongs will be able to appreciate that embodiments of the present disclosure may be implemented in other specific forms in accordance with the technical aspects of the present disclosure. Therefore, it should be understood that the above-described examples embodiments are not restrictive, but rather illustrative in all respects.

What is claimed is:

1. A chemical liquid supply apparatus comprising:
an additive supply comprising:
a first tank configured to receive an additive from an additive container; and
a first circulating pipe connected to the first tank;
a chemical liquid supply comprising:
an auxiliary tank configured to receive a raw etching liquid from a raw etching liquid container and receive the additive from the additive supply; and
a second circulating pipe connected to the auxiliary tank; and
a controller configured to control the additive supply and the chemical liquid supply,
wherein the controller is configured to control the additive supply and the chemical liquid supply so as to:
circulate the additive in the first tank for a first time using the first circulating pipe;
heat the raw etching liquid in the auxiliary tank using a heater such that a temperature of the raw etching liquid is increased from room temperature to a first temperature;
based on the temperature of the raw etching liquid reaching the first temperature, supply the additive to the auxiliary tank; and
produce a chemical liquid by circulating the raw etching liquid and the additive at the first temperature for a second time using the second circulating pipe.

2. The chemical liquid supply apparatus of claim 1, wherein the chemical liquid supply further comprises a main tank that is configured to receive the chemical liquid from the auxiliary tank and store the chemical liquid.

3. The chemical liquid supply apparatus of claim 1, wherein the additive comprises water and silica,
wherein the first time is a time duration elapsed until a concentration of the silica in the additive becomes constant,
wherein the first temperature is in a range of 160° C. to 170° C.,
wherein the second time is a time duration required for dissolving the additive in the raw etching liquid.

4. The chemical liquid supply apparatus of claim 1, wherein the additive supply further comprises:
a liquid particle counter connected to the first circulating pipe and configured to count particles of the additive;
a first supply pipe configured to supply the additive from the additive supply to an auxiliary tank; and
a flow meter connected to the first supply pipe.

5. The chemical liquid supply apparatus of claim 4, wherein the additive comprises water and silica,
wherein the additive supply further comprises a filter connected to the first supply pipe and configured to filter the silica.

6. The chemical liquid supply apparatus of claim 4, wherein the additive supply further comprises a valve connected to the first supply pipe.

7. The chemical liquid supply apparatus of claim 1, wherein the chemical liquid supply further comprises a discharge pipe connected to the second circulating pipe and located within the auxiliary tank.

8. The chemical liquid supply apparatus of claim 7, wherein the auxiliary tank comprises a first area and a second area, below the first area,
wherein the discharge pipe comprises a plurality of holes that are located in the first area of the auxiliary tank.

9. A substrate treating apparatus comprising:
an additive supply comprising:
a first tank configured to receive an additive from an additive container; and
a first circulating pipe connected to the first tank;
a chemical liquid supply comprising:
an auxiliary tank for receiving a raw etching liquid from a raw etching liquid container and receiving the additive from the additive supply;
a second circulating pipe connected to the auxiliary tank; and
a main tank configured to receive and store a chemical liquid from the auxiliary tank;
a processing unit comprising a process chamber, a substrate, and a substrate support, the processing unit configured to receive the chemical liquid from the chemical liquid supply; and
a controller configured to control the additive supply and the chemical liquid supply,
wherein the controller is configured to control the additive supply and the chemical liquid supply so as to:
circulate the additive in the first tank for a first time using the first circulating pipe;
heat the raw etching liquid in the auxiliary tank using a heating device such that a temperature of the raw etching liquid is increased from room temperature to a first temperature;
based on the raw etching liquid reaching the first temperature, supply the additive to the auxiliary tank;
produce the chemical liquid by circulating the raw etching liquid and the additive at the first temperature for a second time using the second circulating pipe; and
supply the chemical liquid to the processing unit.

10. The substrate treating apparatus of claim 9, wherein the processing unit is configured to perform a wet etching process on the substrate using the chemical liquid, and
wherein the substrate treating apparatus further comprises:
a collection tank configured to collect the chemical liquid remaining after the wet etching process;
a recycling tank configured to receive and store the chemical liquid from the collection tank; and
a third circulating pipe connected to the recycling tank.

11. The substrate treating apparatus of claim 10, wherein the controller is further configured to circulate the chemical liquid in the recycling tank at the first temperature for a third time using the third circulating pipe.

12. The substrate treating apparatus of claim 11, wherein the additive comprises water and silica,
wherein the first time is a time duration elapsed until a concentration of the silica in the additive becomes constant,
wherein the first temperature is in a range of 160° C. to 170° C.,
wherein the second time is a time duration required for dissolving the additive in the raw etching liquid,
wherein the third time is a time duration required for dissolving the additive in the chemical liquid that is collected.

13. The substrate treating apparatus of claim 9, the chemical liquid supply further comprises a discharge pipe connected to the second circulating pipe and located in the auxiliary tank.

14. The substrate treating apparatus of claim 13, wherein the auxiliary tank comprises a first area and a second area, below the first area,
wherein the discharge pipe comprises a plurality of holes that are located in the first area of the auxiliary tank.

15. The substrate treating apparatus of claim 9, the additive supply further comprises:
a liquid particle counter connected to the first circulating pipe and configured to count particles of the additive;
a first supply pipe configured to supply the additive from the additive supply to the auxiliary tank; and
a flow meter connected to the first supply pipe.

16. The substrate treating apparatus of claim 15, wherein the additive supply further comprises a valve connected to the first supply pipe.

17. The substrate treating apparatus of claim 9, wherein the chemical liquid supply further comprises:
a concentration meter connected to the second circulating pipe; and
a water container configured to supply water to the auxiliary tank.

18. A chemical liquid supply apparatus comprising:
an additive container containing an additive;
a first tank configured to receive the additive from the additive container and store the additive;
a first circulating pipe connected to the first tank and configured to circulate the additive in the first tank;
a first supply pipe connected to the first circulating pipe and configured to supply the additive, wherein the first supply pipe comprises a filter;
an auxiliary tank configured to receive a raw etching liquid from a raw etching liquid container and receive the additive from the first supply pipe;
a second circulating pipe connected to the auxiliary tank and configured to circulate a chemical liquid in the auxiliary tank, wherein the chemical liquid comprises the raw etching liquid and the additive added to the raw etching liquid;
a heater connected to the second circulating pipe and configured to heat the chemical liquid;
a main tank configured to receive the chemical liquid from the auxiliary tank and store the chemical liquid;
a processing unit comprising a process chamber, a substrate, and a substrate support, the processing unit configured to receive the chemical liquid from the main tank; and
a controller configured to perform control so as to:
circulate the additive in the first tank for a first time using the first circulating pipe;
heat the raw etching liquid in the auxiliary tank using an additional heater such that a temperature of the raw etching liquid is increased from room temperature to a first temperature;
based on the temperature of the raw etching liquid reaching the first temperature, supply the additive to the auxiliary tank;
produce the chemical liquid by circulating the raw etching liquid and the additive at the first temperature for a second time using the second circulating pipe; and
supply the chemical liquid to the main tank.

19. The substrate treating apparatus of claim 18, wherein the auxiliary tank comprises a first area and a second area, below the first area,
wherein the chemical liquid supply apparatus further comprises a discharge pipe connected to the second circulating pipe and located in the first area of the auxiliary tank, and
wherein the discharge pipe comprises a plurality of holes.

20. The substrate treating apparatus of claim 18, further comprising:
a collection tank configured to collect the chemical liquid remaining after use in the processing unit;
a recycling tank configured to receive and store the chemical liquid from the collection tank; and
a third circulating pipe connected to the recycling tank,
wherein the controller is configured to perform the control so as to circulate the chemical liquid stored in the recycling tank for a third time using the third circulating pipe, and then supply the chemical liquid to the auxiliary tank.
